(19) United States
(12) Patent Application Publication
(10) Pub. No.: US 2005/0163022 A1
(43) Pub. Date: Jul. 28, 2005

(54) Coordinate offset adjustment system and coordinate offset adjustment method

(75) Inventor: Toshimitsu Kawasaki, Tokyo (JP)

Correspondence Address: FOLEY AND LARDNER;SUITE 500, 3000 K STREET NW, WASHINGTON, DC, 20007, US

(73) Assignee: NEC CORPORATION

(21) Appl. No.: 11/038,052

(22) Filed: Jan. 21, 2005

(30) Foreign Application Priority Data
Jan. 22, 2004 (JP) 2004-014420

(51) Int. Cl. G01B 11/14; G11B 17/08; G11B 17/04; G11B 19/02; G11B 17/00; G11B 15/18; G05B 19/18; G03F 9/00

(52) U.S. Cl. 369/178.01; 360/69; 700/59; 356/614

(57) ABSTRACT

According to an embodiment, a cartridge sensor shaft is allowed to butt against the vicinity of a positioning hole and is shifted toward the positioning hole. A coordinate offset error is then calculated based on a difference between the moving distance from the portion against which the cartridge sensor shaft butts to the portion at which the cartridge sensor shaft enters the positioning hole and the expected moving distance. The coordinate offset is adjusted by the calculated error. Further, in order to reduce measurement error, the cartridge sensor shaft is allowed to butt from both side of the positioning hole and shifted to detect the edges of the positioning hole, thereby calculating the coordinate offset error based on the two moving distances and two expected moving distances.

### BACKGROUND OF THE INVENTION

1. Field of the Invention:

The present invention relates to a coordinate offset adjustment system and a coordinate offset adjustment method that adjust a coordinate offset, and more particularly to, a coordinate offset system and method that adjust an offset of the stop position of a picker mechanism in a collective magnetic tape drive.

2. Description of the Related Art:

Programs and data used in a computer are, in general, stored in a hard disk drive and transferred, as needed, from the hard disk drive to a main memory at execution time of the program. The hard disk drive is constantly at the risk of being damaged, and a given limitation is imposed on the capacity thereof. Therefore, a backup apparatus that can store a large volume of programs and data with high reliability is required, even if the backup device operates at a low speed. As the backup apparatus, a magneto-optical disk drive, a DVD drive, a tape drive, and the like are available. Among them, a magnetic tape drive is excellent in terms of reliability, storage capacity, and cost-performance, and a collective magnetic tape drive is used in order to back up a tremendous volume of data.

A magazine is mounted on the collective magnetic tape drive. The magazine is proved with a plurality of cells arranged in a matrix form. Each cell houses a magnetic tape cartridge (hereinafter, referred to merely as “cartridge”). An accessor mechanism including a picker mechanism takes out a cartridge required in each occation from a cell that houses the cartridge and feeds the taken out cartridge to a tape drive. After completion of recording or reproduction operation in the tape drive, the accessor mechanism feeds the cartridge from the tape drive to the cell and inserts the cartridge into the cell.

It is necessary that the picker mechanism that includes the cartridge is correctly stopped at the front of the target cell in order to complete the taking-out/insertion operation of the cartridge from/into the target cell normally. Therefore, a servo section that controls the stop position of the picker mechanism must grasp a cell coordinate and determine an offset of the stop position of the picker mechanism based on the cell coordinate.

FIG. 1 is a perspective view showing a conventional detection system of a cell coordinate. Reference numeral 901 denotes a picker mechanism attached to an accessor mechanism that feeds a cartridge between a cell and a tape drive. Reference numeral 902 denotes an entrance of the magazine, which has a plurality of cell slots. The picker mechanism 901 includes a light emitting element 903 and a light receiving element 904. The entrance 902 includes a Y-direction position detection hole 905 for each cell. The light emitted from the light emitting element 903 is received by the light receiving element 904 unless there is an obstacle in its path. In order to detect a Y-coordinate of each cell, the following operation is performed for each cell. The operation includes: shifting the picker mechanism 901 from bottom to top (in the direction in which Y-coordinate increases) in the vicinity of the Y-direction position detection hole 905; detecting the Y-coordinate of the picker mechanism 901 at the time when the light once intercepted in the peripheral portion of the Y-direction position detection hole 905 again enters the light receiving element 904 to allow the intensity of the light to be received by the light receiving element 904 to reach a predetermined threshold value; then shifting the picker mechanism 901 from top to bottom (in the direction in which Y-coordinate decreases) in the vicinity of the Y-direction position detection hole 905; detecting the Y-coordinate of the picker mechanism 901 at the time when the light once intercepted in the peripheral portion of the Y-direction position detection hole 905 again enters the light receiving element 904 to allow the intensity of the light to be received by the light receiving element 904 to reach a predetermined threshold value; and setting an average value of the detected two Y-coordinates as the Y-coordinate of the cell.

However, there is the following problem with the above system.

A long distance between the light emitting element 903 and light receiving element 904 makes it difficult to align the optical axes of the both elements such that the light emitted from the light emitting element 903 reaches the light receiving element 904.

Further, a cartridge 106 as shown in FIG. 2 is to be inserted into a cell. In most cases, a white label 912 for bar code printing and the like is affixed to the cartridge 106. Therefore, there is a possibility that a part of the light emitted from the light emitting element 903 illuminates the label 912, and the light reflected by the label 912 enters the light receiving element 904. As a result, the light receiving element 904 makes an error detection of the light in some cases. Further, error detections have occurred due to diffused reflection or ambient light.

### SUMMARY OF THE INVENTION

An object of the present invention is therefore to provide a coordinate offset adjustment system and a coordinate offset adjustment method capable of adjusting a coordinate offset without an occurrence of the error due to diffused reflection or ambient light.

According to an aspect of the present invention, there is provided a coordinate offset adjustment system including: a reference point detection probe placement means for placing a reference point detection probe in a vicinity of a reference point; reference point detection probe shift means for shifting the reference point detection probe toward the reference point; a reference point detection means for, using the reference point detection probe, detecting the reference point while said reference point detection probe shift means shifts the reference point detection probe; and an offset adjustment means for adjusting a coordinate offset based on a moving distance between a position of the reference point detection probe at which said reference point detection probe placement means places the reference point detection probe and a position of the reference point detection probe at which said reference point detection means detects the reference point.

In the above coordinate offset adjustment system, the position at which said reference point detection probe placement means places the reference point detection probe may be a position apart from an expectation reference point by a predetermined distance, the expectation reference point being a point that the reference point is supposed to be positioned, which is obtained based on the current offset, and said offset adjustment means may add a difference between the moving distance and a predetermined distance to the current offset to obtain a new offset.

In the above coordinate offset adjustment system, said reference point detection probe placement means, said reference point detection probe shift means, and said reference point detection means may perform the placement, the shift, the detection at least two times in different directions, respectively, to obtain two or more moving distances, and said offset adjustment means may adjust the coordinate offset based on the two or more moving distances.

In the above coordinate offset adjustment system, the reference point detection probe may be a mechanical probe, and the reference point may belong to a boundary having a mechanical step and may be detected based on a displacement of the mechanical probe in the boundary.

In the above coordinate offset adjustment system, the mechanical probe may be a shaft.

In the above coordinate offset adjustment system, the shaft may further have a function of detecting a cartridge that has been inserted into a cell.

In the above coordinate offset adjustment system, the reference point detection probe may be an optical probe, the reference point may belong to a boundary having an optical difference, and the reference point detection probe may be an optical probe detecting the optical difference in the boundary to detect the reference point.

According to the present invention, detecting the reference point using the reference point detection probe enables the coordinate offset to be adjusted based on the moving distance.

According to the present invention, measurement error can be reduced.

According to the present invention, errors due to diffused reflection or ambient light do not occur.

According to the present invention, the need of dedicated probe for coordinate offset adjustment is eliminated, thereby to reduce cost, space, and the like.

According to the present invention, a configuration that is not influenced by diffused reflection nor ambient light can be obtained.

### BRIEF DESCRIPTION OF THE DRAWINGS

FIG. 1 is a perspective view showing a mechanism including a cell coordinate detection system according to a conventional art;

FIG. 2 is a perspective view showing a tape cartridge;

FIG. 3 is a perspective view showing a collective tape drive according to an embodiment of the present invention;

FIG. 4 is a perspective view showing a magazine according to the embodiment of the present invention;

FIG. 5 is a perspective view showing a picker mechanism according to the embodiment of the present invention;

FIG. 6 is a perspective view showing a vertical positioning hole included in the magazine and the peripheral portion thereof according to the embodiment of the present invention;

FIG. 7 is a block diagram showing an electrical system for performing a coordinate offset adjustment method according to the embodiment of the present invention;

FIG. 8 is a first flowchart for explaining the coordinate offset adjustment method according to the embodiment of the present invention;

FIG. 9 is a second flowchart for explaining the coordinate offset adjustment method according to the embodiment of the present invention;

FIG. 10 is a third flowchart for explaining the coordinate offset adjustment method according to the embodiment of the present invention;

FIG. 11 is a fourth flowchart for explaining the coordinate offset adjustment method according to the embodiment of the present invention;

FIG. 12 is a perspective view showing a state where a cartridge sensor shaft according to the embodiment of the present invention butts against a contact portion; and

FIG. 13 is a view for explaining a calculation formula for calculating an offset value to be used in the coordinate offset adjustment method according to the embodiment of the present invention.

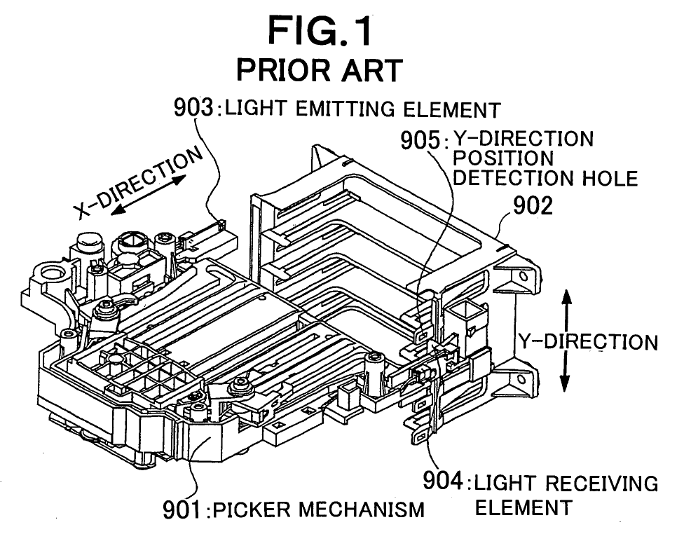

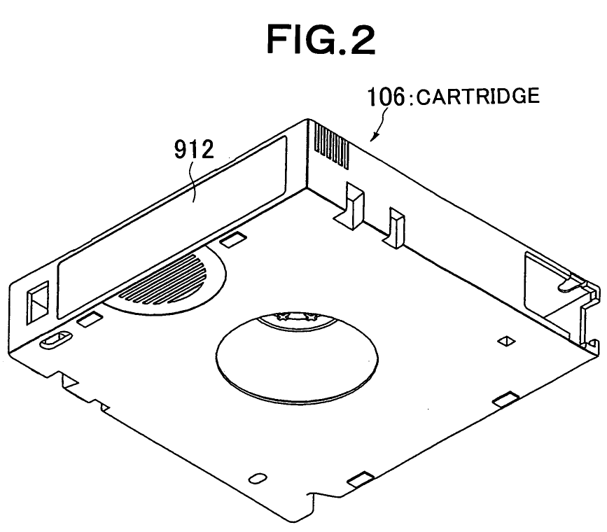

### DETAILED DESCRIPTION OF THE PREFERRED EMBODIMENTS

A preferred embodiment of the present invention will be described below in detail with reference to the accompanying drawings.

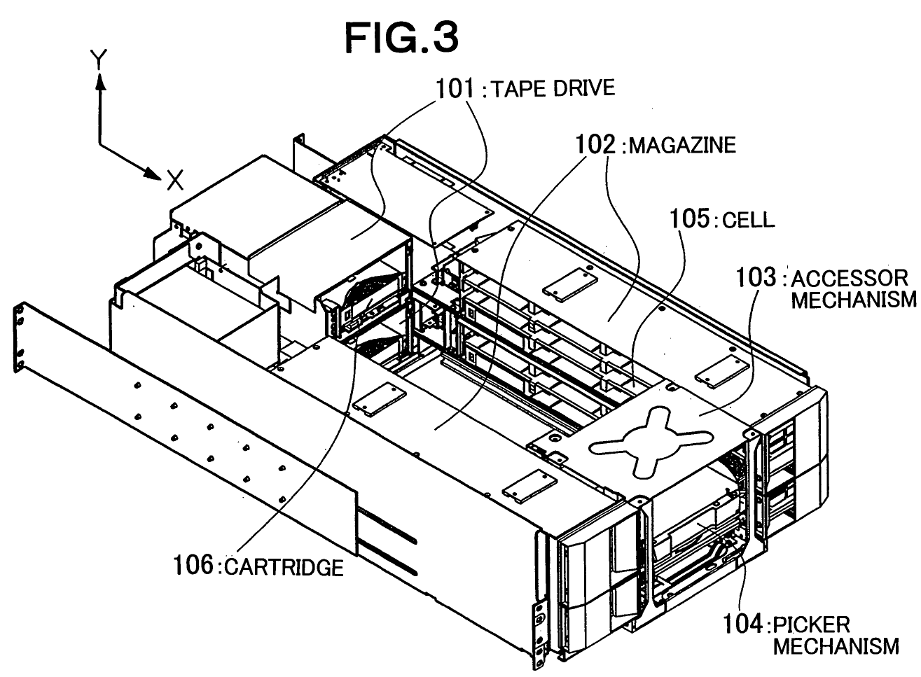

FIG. 3 is a perspective view showing a collective magnetic tape drive according to an embodiment of the present invention. The collective magnetic tape-drive includes a tape drive 101, two magazines 102 and an accessor mechanism 103. Each of the magazines 102 includes a plurality of cells 105 arranged two dimensionally in X and Y directions. A cartridge 106 is housed in each of the cell 105. The accessor mechanism 103 includes a picker mechanism 104. The main body of the accessor mechanism 103 is movable in X-direction. The picker mechanism 104 is movable in Y-direction and can be rotated about Y-axis.

In order to complete loading of the cartridge 106 that has been inserted into a certain cell into the tape drive 101, the following operation is performed. That is, the position of the accessor mechanism 103 in X-direction is firstly shifted to the stop position corresponding to the position of the target cell in X-direction, the position of the picker mechanism 104 in Y-direction is then shifted to the stop position corresponding to the position of the target cell in Y-direction, the picker mechanism 104 is rotated to face the magazine 102 including the target cell, whereby the picker mechanism 104 faces the front of the target cell. After that, as described later, the cartridge 106 is taken out of the target cell and loaded into the picker mechanism 104. Then the accessor mechanism 103 is shifted in X-direction, and the picker mechanism 104 is shifted in Y-direction and rotated to face the tape drive 101. The cartridge 106 is then unloaded from the picker mechanism 104 and loaded into the tape drive 101.

When the cartridge 106 that has been loaded into the tape drive 101 is set back to the cell, the operation opposite to the above is performed.

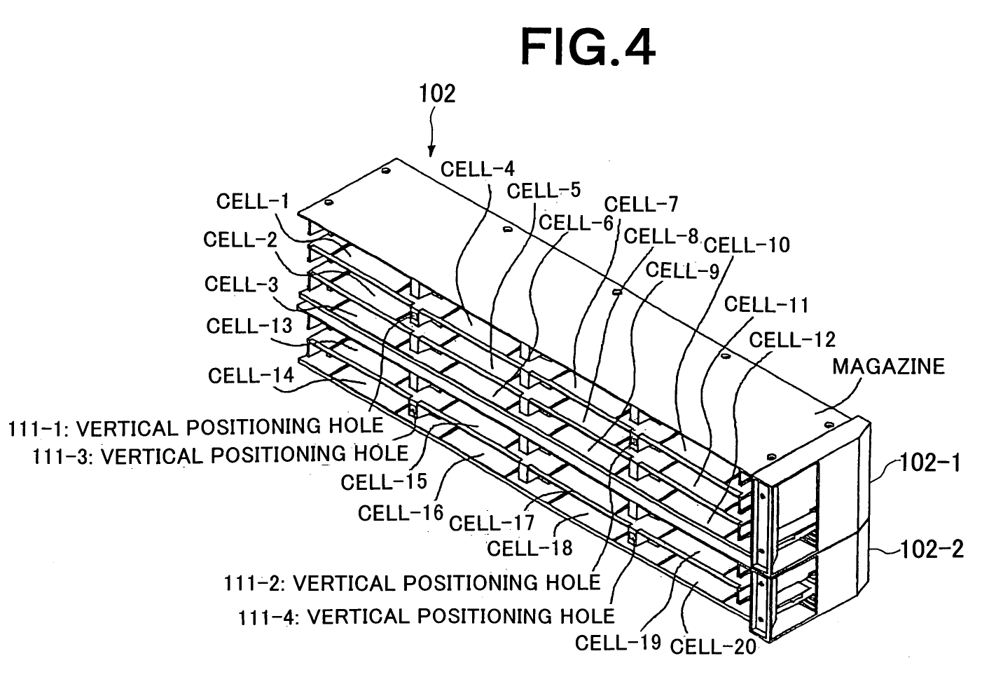

Referring to FIG. 4, the magazine 102 is divided into a first magazine 102-1 and second magazine 102-2. The first magazine 102-1 includes a cell-1 to cell-12. The second magazine 102-2 includes a cell-13 to cell-20. Further, the first magazine 102-1 includes vertical (Y-direction) positioning holes 111-1 and 111-2, and second magazine 102-2 includes vertical positioning holes 111-3 and 111-4.

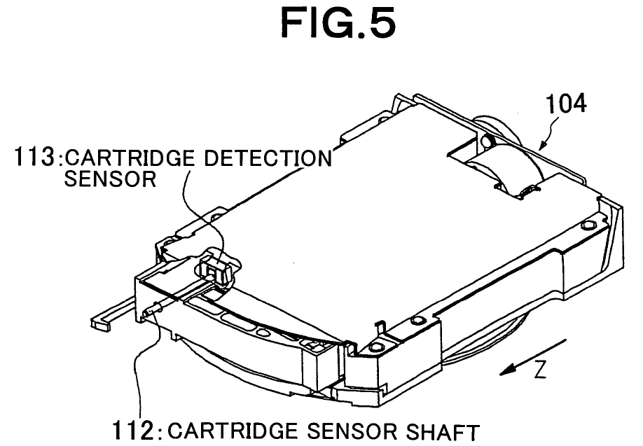

Referring to FIG. 5, the picker mechanism 104 includes a cartridge sensor shaft 112 and a cartridge detection sensor 113. The cartridge sensor shaft 112 and cartridge detection sensor 113 are mounted on a slide mechanism and can be shifted forward and backward in Z-axis direction in an integrated manner. Further, the cartridge sensor shaft 112 is extensible in Z-axis direction relative to the slide mechanism and is pushed or pulled in the extension direction by an elastic member such as a coil spring and the like. The cartridge detection sensor 113 detects whether the cartridge sensor shaft 112 is extending or retracting with respect to the slide mechanism.

Therefore, whether the cartridge 106 has been inserted into a certain cell 105 or not is detected as follows: the picker mechanism 104 is shifted to the front of the target cell 105; the slide mechanism is forwarded in Z-axis direction; and the cartridge detection sensor 113 detects at this time whether the cartridge sensor shaft 112 butts against the cartridge 106 and retracts.

In the present embodiment, the cartridge sensor shaft 112, cartridge detection sensor 113, and slide mechanism are used also for Y-coordinate offset adjustment, eliminating the need of dedicated parts for Y-coordinate offset adjustment to reduce cost.

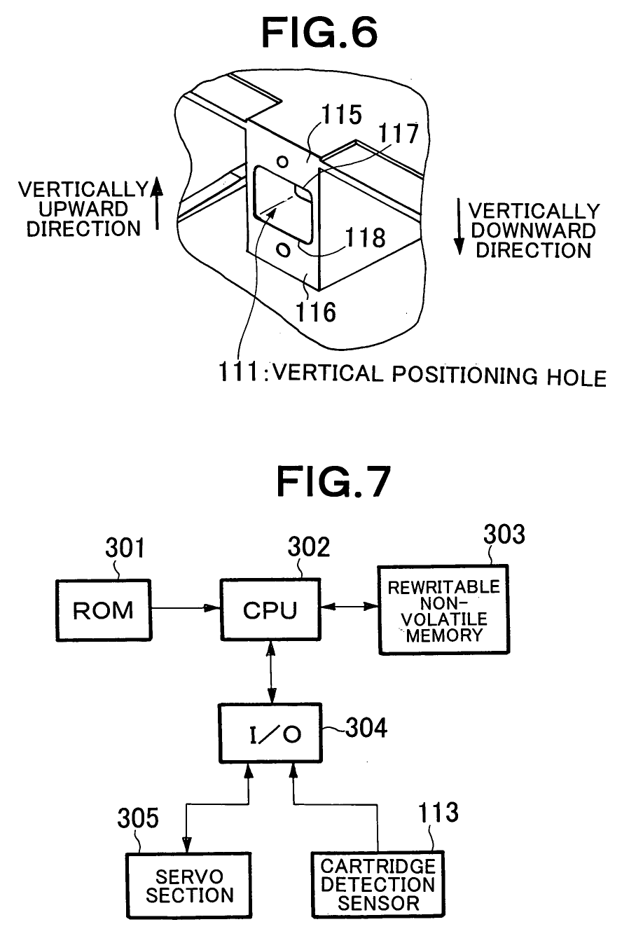

FIG. 6 is an enlarged view of the vertical positioning hole 111 and the peripheral portion thereof. The upper and lower parts of the vertical positioning hole 111 serve as an upper side contact portion 115 and lower side contact portion 116, respectively. The line segment denoted by reference numeral 117 is the boundary between the vertical positioning hole 111 and upper side contact portion 115, and the line segment denoted by reference numeral 118 is the boundary between the vertical positioning hole 111 and lower side contact portion 116. An upper side reference point to be described later belongs to the boundary 117, and a lower side reference point belongs to the boundary 118.

Next, a coordinate offset adjustment method according to the present embodiment will be described. As shown in FIG. 7, the coordinate offset adjustment method is performed using a ROM 301, a CPU 302, a rewritable nonvolatile memory 303, an input/output interface (I/O) 304, a servo section 305, a cartridge detection sensor 113 and the like. The CPU 302 reads in and executes a program stored in the ROM 301 to perform each process of the coordinate offset adjustment method. The rewritable nonvolatile memory 303 stores stop positions in X- and Y-directions corresponding to each cell, and a stop position in X-direction, a center position in Y-direction, and a moving distance of the slide mechanism corresponding to each vertical positioning hole 111. In the case of accessing a cell, the servo section 305 shifts the accessor mechanism 103 to the stop position in X-direction corresponding to a target cell and the peripheral portion thereof and shifts the picker mechanism 104 to the stop position in Y-direction corresponding to the target cell and the peripheral portion thereof In the case of adjusting a position offset, the servo section 305 shifts the accessor mechanism 103 to the stop position in X-direction corresponding to a target vertical positioning hole 111 and controls the picker mechanism 104 in the vicinity of the center position in Y-direction corresponding to the target vertical positioning hole 111. The I/O 304 interfaces between the CPU 302 and servo section 305 and between the CPU 302 and cartridge detection sensor 113.

An offset is included in the center position in Y-direction corresponding to each vertical positioning hole 111, and the offset is compensated by the coordinate offset adjustment method. An offset is also included in the stop position in Y-direction corresponding to each cell. The vertical positioning hole 111-1 has a first offset common among the cell-1 to cell-6 located in the vicinity thereof, the vertical positioning hole 111-2 has a second offset common among the cell-7 to cell-12 located in the vicinity thereof, the vertical positioning hole 111-3 has the second offset common among the cell-13 to cell-16 located in the vicinity thereof, and the vertical positioning hole 111-4 has the second offset common among the cell-17 to cell-20 located in the vicinity thereof.

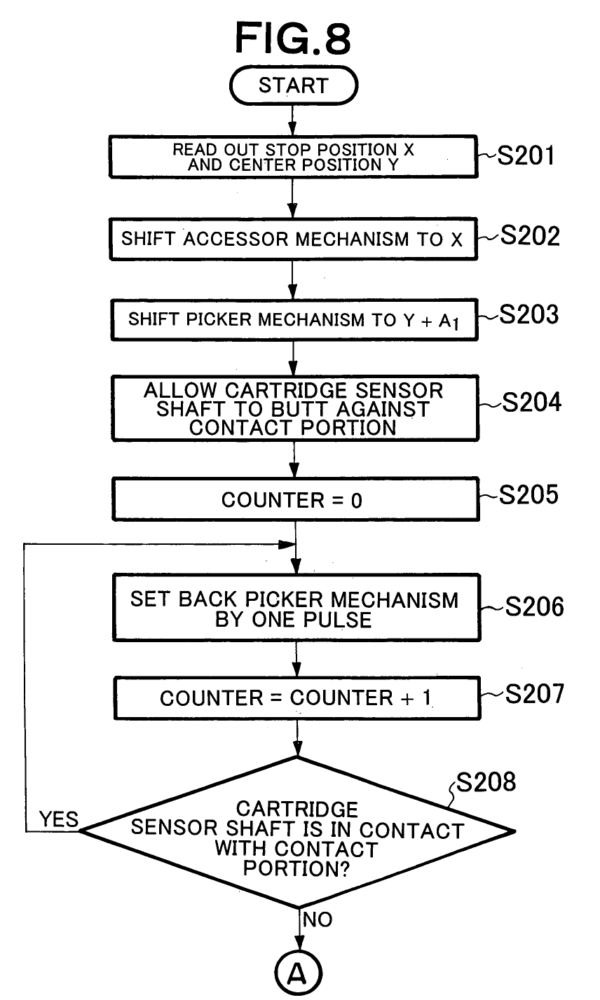

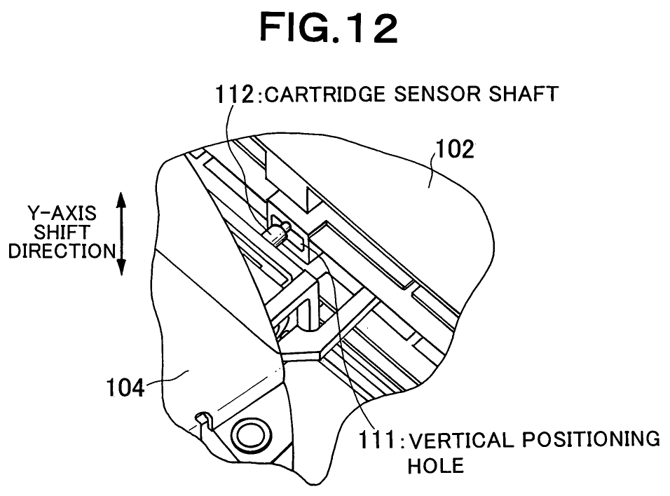

Referring to FIG. 8, firstly, the stop position X in X-direction and center position Y in Y-direction corresponding to a target vertical positioning hole 111 are read out from the rewritable nonvolatile memory 303 (step S 201). Next, the accessor mechanism 103 is shifted to the stop position X in X-direction read out in step S201 (step S202). Then, the picker mechanism 104 is shifted to the position obtained by adding a value A₁ to the center position Y in Y-direction read out in step 201 (step S203). The value A₁ has been determined such that the cartridge sensor shaft 112 butts against the contact portion 115 without fail when the slide mechanism is forwarded under the condition that the difference between the offset currently retained and actual offset is not more than the allowable value. Next, the slide mechanism is forwarded to allow the cartridge sensor shaft 112 to butt against the contact portion 115 (step S204). The positional relationship between the cartridge sensor shaft 112 and vertical positioning hole 111 at this stage is shown in FIG. 12. Next, a counter is initialized to 0 (step S205). The picker mechanism 104 is then set back in Y-axis direction by one pulse (step S206). The term “pulse” mentioned here is a pulse used in position servo and the like of the picker mechanism. 104 and is generated by a rotary encoder and the like. Next, the counter is incremented by 1 (step S207). It is then determined whether the cartridge sensor shaft 112 still in contact with the contact potion 115 based on a detection signal from the cartridge detection sensor 113 (step S208). When it has been determined that the cartridge sensor shaft 112 has been still in contact with the contact portion 115 (Yes in step S208), the flow returns to step S206.

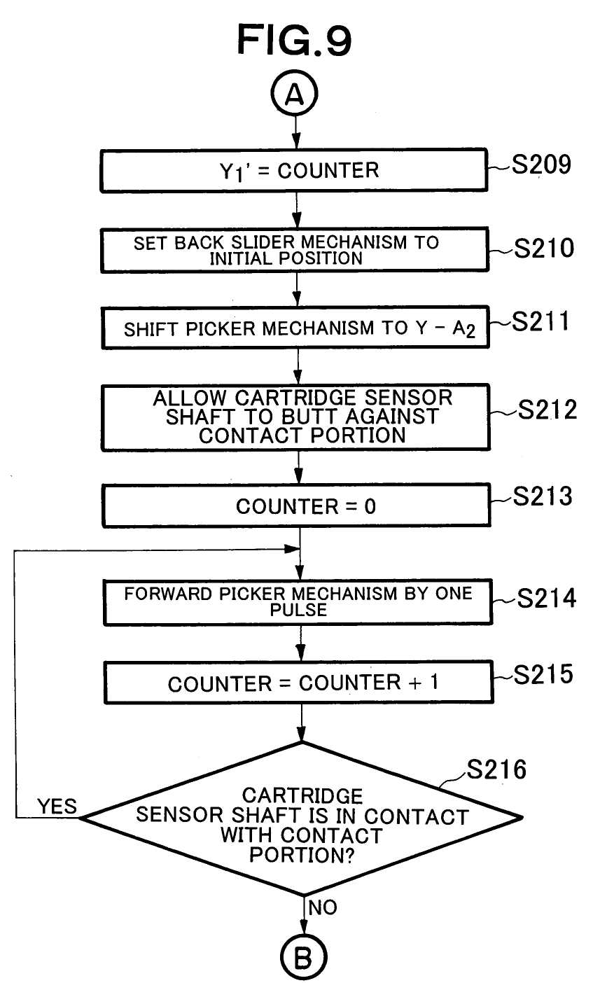

Referring to FIG. 9, when the cartridge sensor shaft 112 is shifted away from the contact portion 115 and enters the vertical positioning hole 111 (No in step S208), the counter value is assigned to a variable y1′ (step S209). Then the slider mechanism is set back to the initial position so that the cartridge sensor shaft 112 does not butt against the contact portions 115 and 116 even when the picker mechanism 104 is shifted (step S210).

Next, the picker mechanism 104 is shifted to the position obtained by subtracting a value A₂ from the center position Y in Y-direction read out in step S201 (step S211). The value A₂ has been determined such that the cartridge sensor shaft 112 butts against the contact portion 116 without fail when the slide mechanism is forwarded under the condition that the difference between the offset currently retained and actual offset is not more than the allowable value. Next, the slide mechanism is forwarded to allow the cartridge sensor shaft 112 to butt against the contact portion 115 (step S212). The counter is then initialized to 0 (step S213). The picker mechanism 104 is forwarded in Y-axis direction by one pulse (step S214). The counter is then incremented by 1 (step S215). It is then determined whether the cartridge sensor shaft 112 still in contact with the contact potion 116 based on a detection signal from the cartridge detection sensor 113 (step S216). When it has been determined that the cartridge sensor shaft 112 has been still in contact with the contact portion 116 (Yes in step S216), the flow returns to step S214.

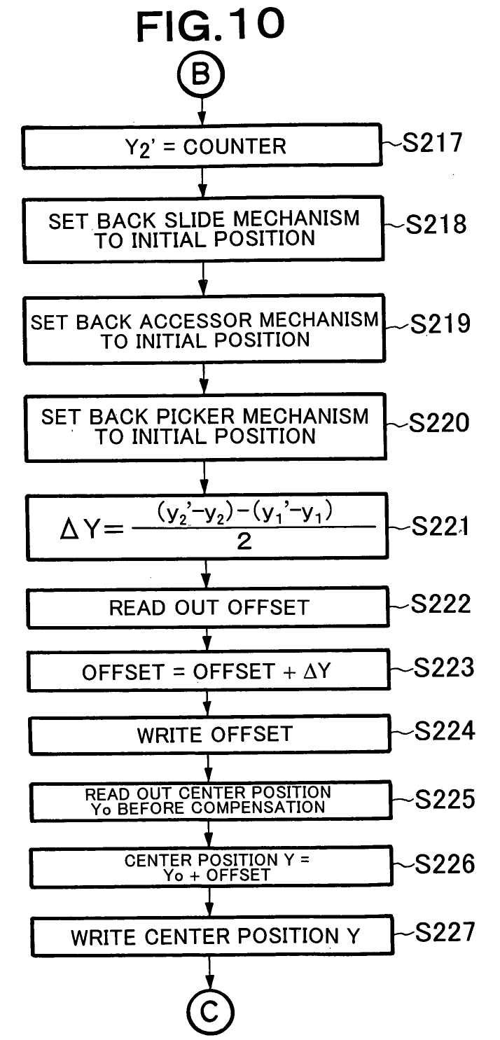

Referring to FIG. 10, when the cartridge sensor shaft 112 is shifted away from the contact portion 116 and enters the vertical positioning hole 111 (No in step S216), the counter value is assigned to a variable y2′ (step S217). Then the slider mechanism is set back (step S218) so that the cartridge sensor shaft 112 does not butt against the contact portions 115 and 116 even when the accessor mechanism 103 and picker mechanism 104 are shifted. Then the accessor mechanism 103 and picker mechanism 104 are set back to the initial positions (steps S219, S220).

An offset error AY is calculated by the following equation (step S221).

$$Δ Y = \frac{( {y}_{2}^{′} - {y}_{2} ) - ( {y}_{1}^{′} - {y}_{1} )}{2} \qquad ( 1 )$$

An offset is then read out from the rewritable nonvolatile memory 303 (step S222) and updated by adding the offset error ΔY that has been calculated in step S221 to the offset that has been read out in step S222 (step S223). The offset that has been updated in step S223 is then written into the rewritable nonvolatile memory 303 (step S224).

Next, a center position Yo in Y-direction before compensation is read out from the rewritable nonvolatile memory 303 (step S225), and a new center position Y in Y-direction is then obtained by adding the offset that has been updated in step S223 to the center position Yo in Y-direction before compensation that has been read out in step S225 (step S226). The center position Y in Y-direction that has been obtained in step S226 is then written into the rewritable nonvolatile memory 303 (step S227).

In place of steps S225 to 227, the following operation may be performed. That is, the current center position Y in Y-direction is read out from the rewritable nonvolatile memory 303, the offset error ΔY that has been calculated in step S221 is added to the read out center position Y in Y-direction to update the center position Y in Y-direction, and the updated center position Y in Y-direction is written into the rewritable nonvolatile memory 303. By this, it is possible to cope with the case where the center position Y in Y-direction has been changed by factors other than the offset that has been updated in step S223.

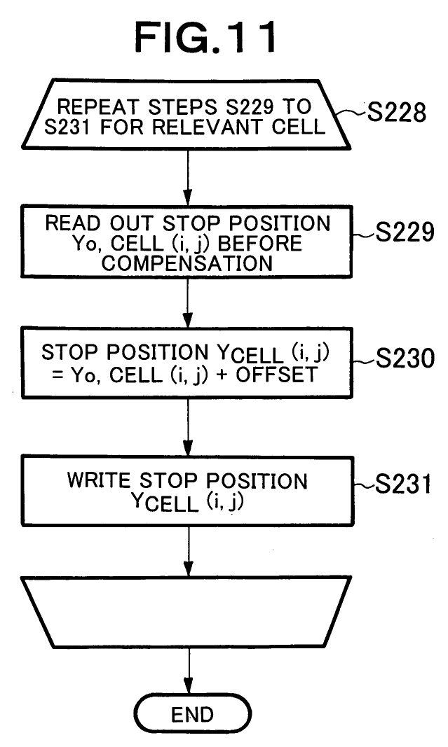

Referring to FIG. 11, steps S229 to S231 are repeated for each cell having common offset value with respect to the vertical positioning hole 111 (step S228).

In step S229, a Y-direction stop position before compensation Yo,_{CELL} (i, j) related to the target cell is read out from the rewritable nonvolatile memory 303. Next, a new Y-direction stop position Y_{CELL} (i, j) is obtained by adding the offset that has been updated in step S223 to the Y-direction stop position before compensation Yo,_{CELL} (i, j) that has been read out in step S229 (step S230). The Y-direction stop position Y_{CELL} (i, j) that has been obtained in step S230 is written into the rewritable nonvolatile memory 303.

In place of steps S229 to S231, the following operation may be performed. That is, the current Y-direction stop position Y_{CELL} (i, j) is read out from the rewritable nonvolatile memory 303, the offset error that has been calculated in step S221 is added to the read out Y-direction stop position Y_{CELL} (i, j) to update the Y-direction stop position Y_{CELL} (i, j), and the updated Y-direction stop position Y_{CELL} (i,j) is written into the rewritable nonvolatile memory 303. By this, it is possible to cope with the case where the Y-direction stop position Y_{CELL} (i, j) has been changed by factors other than the offset that has been updated in step S223.

A description will next be given of the equation (1).

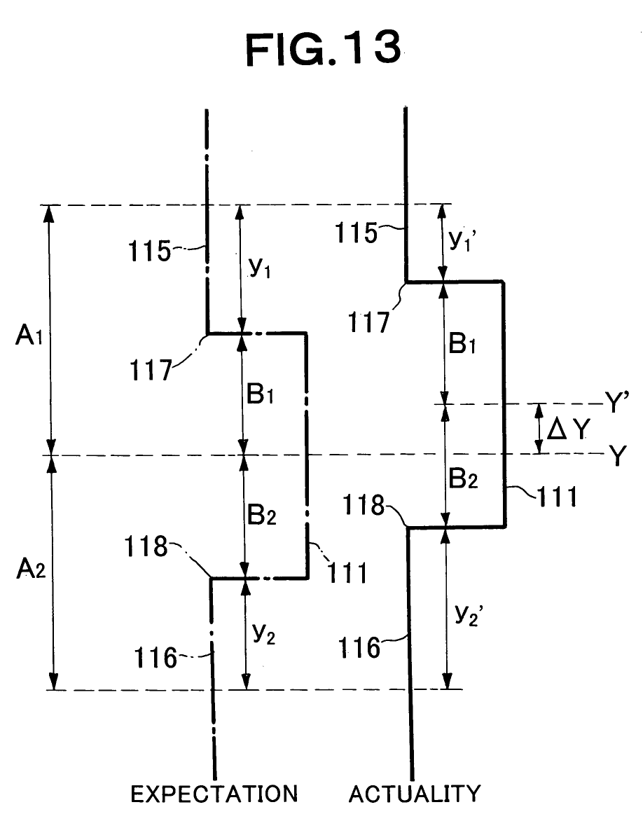

Referring to FIG. 13, a Y-direction center position Y is set in the vicinity of the center of the vertical positioning hole 111. The length from the boundary 117 to the Y-direction center position Y is assumed to be B₁, and the length from the boundary 118 to the Y-direction center position Y is assumed to be B₂. Further, lengths A₁ and A₂ are set as described above. With this condition, it cab be seen from FIG. 13 that the distance y1 that is obtained by repeating steps S206 to S208 unless there is offset error becomes
y₁=A₁−B₁
and the distance y2 that is obtained by repeating steps S214 to S216 unless there is offset error becomes
y₂=A₂−B₂.

On the other hand, it can be seen from FIG. 13 that the distance y₁′ that is obtained by repeating steps S206 to S208 when there is the offset error ΔY becomes
y_{1′}=y₁−ΔY,
and the distance Y₂′ that is obtained by repeating steps S214 to S216 when there is the offset error ΔY becomes
y_{2′}=y₂−ΔY

Therefore, as to the offset ΔY,
ΔY=y₁−y_{1′} . . . (2) or
ΔY=−t₂+y_{2′} . . . (3)
is satisfied. Since y₁ and y₂ has been known, the offset error ΔY can be obtained by assigning y₁ and y₂ and measured y₁ and y₂ to the above equations. Although the offset error ΔY can be obtained using only one of the above two equations, the average of the results from the two equations can reduce further measurement error. It is the equation (1) that takes the average. Therefore, if there is an advantage greater than the advantage that reduces the measurement error, the offset error may be obtained by using only the equation (2) or the equation (3).

In the above description, the cartridge sensor shaft is used. Alternatively, however, a plate or block may be used. Further, as long as the problem of the conventional art can be solved, optical distance measuring equipment (for example, equipment using a laser light) may be used in place of the cartridge sensor shaft. Further, two objects having different optical characteristics (for example, reflectance, and deflection characteristics) may be used in place of the vertical positioning hole 111 and contact portion and a difference between the two may be detected by an optical detection apparatus (for example, an apparatus having an integrated pair of light emitting section and light receiving section, or the apparatus obtained by adding a deflection glass). In the present invention, an object having a function of detecting a reference point belonging to the boundary 117 and 118, such as the cartridge sensor shaft, plate, block, optical detection apparatus, and the like is defined as a reference point detection probe. Further, the distance measurement by a laser may be adopted.

1. A coordinate offset adjustment system comprising:
reference point detection probe placement means for placing a reference point detection probe in a vicinity of a reference point;
reference point detection probe shift means for shifting the reference point detection probe toward the reference point;
reference point detection means for, using the reference point detection probe, detecting the reference point while said reference point detection probe shift means shifts the reference point detection probe; and
offset adjustment means for adjusting a coordinate offset based on a moving distance between a position of the reference point detection probe at which said reference point detection probe placement means places the reference point detection probe and a position of the reference point detection probe at which said reference point detection means detects the reference point.

2. The coordinate offset adjustment system according to claim 1, wherein
the position at which said reference point detection probe placement means places the reference point detection probe is a position apart from an expectation reference point by a predetermined distance, the expectation reference point being a point that the reference point is supposed to be positioned, which is obtained based on a current offset, and
said offset adjustment means adds a difference between the moving distance and a predetermined distance to the current offset to obtain a new offset.

3. The coordinate offset adjustment system according to claim 1, wherein
said reference point detection probe placement means, said reference point detection probe shift means, and said reference point detection means perform the placement, the shift, the detection at least two times in different directions, respectively, to obtain two or more moving distances, and
said offset adjustment means adjusts the coordinate offset based on the two or more moving distances.

4. The coordinate offset adjustment system according to claim 1, wherein
the reference point detection probe is a mechanical probe, and
the reference point belongs to a boundary having a mechanical step and is detected based on a displacement of the mechanical probe in the boundary.

5. The coordinate offset adjustment system according to claim 4, wherein the mechanical probe is a shaft.

6. The coordinate offset adjustment system according to claim 5, wherein the shaft further has a function of detecting a cartridge that has been inserted into a cell.

7. The coordinate offset adjustment system according to claim 1, wherein
the reference point detection probe is an optical probe
the reference point belongs to a boundary having an optical difference, and
the reference point detection probe is an optical probe detecting the optical difference in the boundary to detect the reference point.

8. A coordinate offset adjustment method comprising:
a reference point detection probe placement step of placing a reference point detection probe in a vicinity of a reference point;
a reference point detection probe shift step of shifting the reference point detection probe toward the reference point;
a reference point detection step of, using the reference point detection probe, detecting the reference point while said reference point detection probe shift step shifts the reference point detection probe; and
an offset adjustment step of adjusting a coordinate offset based on a moving distance between a position of the reference point detection probe at which said reference point detection probe placement step has been performed and the position of the reference point detection probe at which said reference point detection step has been performed.

9. The coordinate offset adjustment method according to claim 8, wherein
the position at which said reference point detection probe placement step places the reference point detection probe is a position apart from an expectation reference point by a predetermined distance, the expectation reference point being a point that the reference point is supposed to be positioned, which is obtained based on a current offset, and
said offset adjustment step adds a difference between the moving distance and a predetermined distance to the current offset to obtain a new offset.

10. The coordinate offset adjustment method according to claim 8, wherein
said reference point detection probe placement step, said reference point detection probe shift step, and said reference point detection step are performed at least two times in different directions, respectively, to obtain two or more moving distances, and
said offset adjustment step adjusts the coordinate offset based on the two or more moving distances.

11. The coordinate offset adjustment method according to claim 8, wherein
the reference point detection probe is a mechanical probe, and
the reference point belongs to a boundary having a mechanical step and is detected based on a displacement of the mechanical probe in the boundary.

12. The coordinate offset adjustment method according to claim 11, wherein the mechanical probe is a shaft.

13. The coordinate offset adjustment method according to claim 12, wherein the shaft further has a function of detecting a cartridge that has been inserted into a cell.

14. The coordinate offset adjustment method according to claim-8, wherein
the reference point detection probe is an optical probe
the reference point belongs to a boundary having an optical difference, and
the reference point detection probe is an optical probe detecting the optical difference in the boundary to detect the reference point.
